(19) United States
(12) Patent Application Publication
(10) Pub. No.: US 2025/0263831 A1
(43) Pub. Date: Aug. 21, 2025

(54) FILM FORMING METHOD AND FILM FORMING APPARATUS

(71) Applicant: Tokyo Electron Limited, Tokyo (JP)

(72) Inventors: Shinichi IKE, Nirasaki City (JP); Shuji AZUMO, Nirasaki City (JP); Yumiko KAWANO, Nirasaki City (JP); Tomohiro NAKAGAWA, Nirasaki City (JP); Yusaku KASHIWAGI, Nirasaki City (JP)

(21) Appl. No.: 19/187,043

(22) Filed: Apr. 23, 2025

Related U.S. Application Data
(63) Continuation of application No. PCT/JP2023/037417, filed on Oct. 16, 2023.

(30) Foreign Application Priority Data
Oct. 28, 2022 (JP) 2022-173129

(51) Int. Cl. C23C 16/04; C23C 16/44; C23C 16/455; C23C 16/52

(52) U.S. Cl. CPC C23C 16/04; C23C 16/4405; C23C 16/45529; C23C 16/45534; C23C 16/45536; C23C 16/52

(57) ABSTRACT

A film forming method includes (A) preparing a substrate including a first film and a second film made of a material different from that of the first film in different regions of a surface of the substrate, (B) selectively forming a self-assembled monolayer on a surface of the second film with respect to a surface of the first film, using an organic compound, (C) after the (B), supplying a removal gas for removing the organic compound attached to the surface of the first film onto the surface of the substrate, and (D) after the (C), forming a target film on the surface of the first film while suppressing formation of the target film on the surface of the second film, using the self-assembled monolayer.

### CROSS-REFERENCE TO RELATED APPLICATION

This application is a bypass continuation application of International Application No. PCT/J P2023/037417 having an international filing date of Oct. 16, 2023 and designating the United States, the international application being based upon and claiming the benefit of priority from Japanese Patent Application No. 2022-173129, filed on Oct. 28, 2022, the entire contents of which are incorporated herein by reference.

### TECHNICAL FIELD

The present disclosure relates to a film forming method and a film forming apparatus.

### BACKGROUND

Patent Document 1 describes a film forming method of, while suppressing formation of a target film on a portion (e.g., a surface of a conductive film) of a substrate surface by using a self-assembled monolayer (SAM), forming the target film on another portion (e.g., a surface of an insulating film) of the substrate surface. In Patent Document 1, before the SAM is formed, a natural oxide film formed on the surface of the conductive film is removed, and a metal oxide film is formed on the surface of the conductive film. The metal oxide film has a uniform film quality as compared with the natural oxide film. The SAM is formed on the surface of the conductive film while reducing the metal oxide film.

### PRIOR ART DOCUMENT

### Patent Document

Patent Document 1: Japanese Patent Laid-Open Publication No. 2021-057563

### SUMMARY

According to one embodiment of the present disclosure, there is provided a film forming method including (A) preparing a substrate including a first film and a second film made of a material different from that of the first film in different regions of a surface of the substrate, (B) selectively forming a self-assembled monolayer on a surface of the second film with respect to a surface of the first film, using an organic compound, (C) after the (B), supplying a removal gas for removing the organic compound attached to the surface of the first film onto the surface of the substrate, and (D) after the (C), forming a target film on the surface of the first film while suppressing formation of the target film on the surface of the second film, using the self-assembled monolayer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to an embodiment.

FIG. 2 is a flowchart illustrating an example of a subroutine of step S106.

FIG. 3A is a view illustrating an example of step S101.

FIG. 3B is a view illustrating an example of step S102.

FIG. 3C is a view illustrating an example of step S103.

FIG. 3D is a view illustrating an example of step S104.

FIG. 3E is a view illustrating an example of step S105.

FIG. 3F is a view illustrating an example of the step S106.

FIG. 4 is a flowchart illustrating a film forming method according to a modification.

FIG. 5A is a view illustrating a modification of the step S104.

FIG. 5B is a view illustrating a modification of the step S105.

FIG. 5C is a view illustrating an example of a substrate after performing the steps S104 and S105 N times.

FIG. 6 is a plan view illustrating a film forming apparatus according to an embodiment.

FIG. 7 is a cross-sectional view illustrating an example of a first processor of FIG. 6.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments are described with reference to the accompanying drawings. Throughout the drawings, the same or corresponding members or components are denoted by the same or corresponding reference numerals, and duplicated descriptions are omitted.

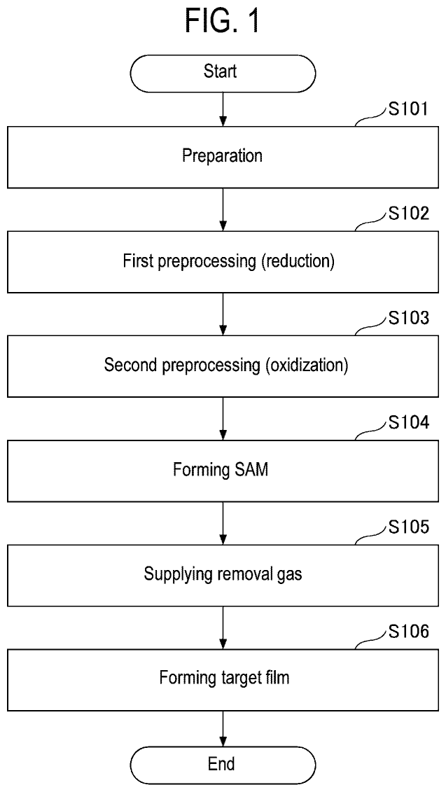

A film forming method according to an embodiment is described with reference to FIGS. 1, 2, and 3A to 3F. The film forming method includes, for example, steps S101 to S106 shown in FIG. 1. Further, the film forming method may include at least the steps S101 and S104 to S106. The film forming method may not include the steps S102 and S103. Further, the film forming method may include steps in addition to the steps S101 to S106 shown in FIG. 1.

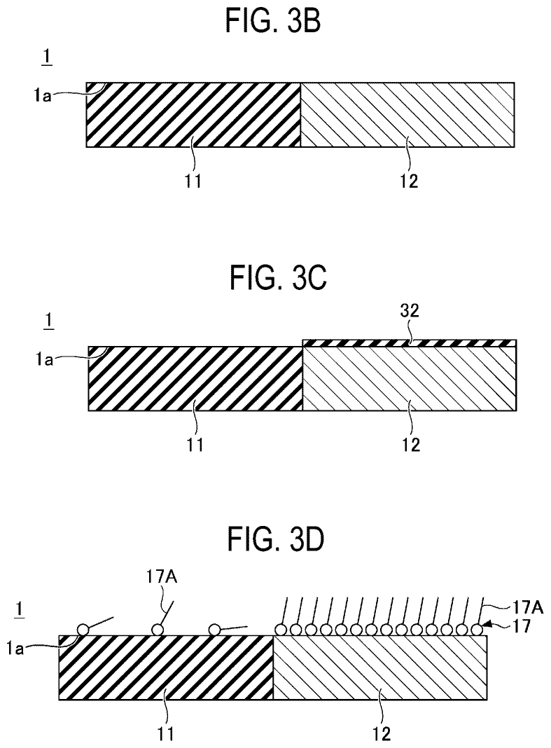

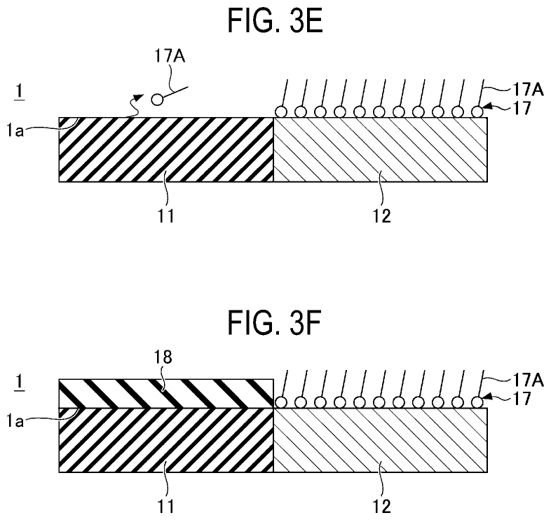

The step S101 of FIG. 1 includes preparing a substrate as illustrated in FIG. 3A. The substrate 1 includes an insulating film 11 and a conductive film 12 in different regions of a substrate surface 1a. The substrate surface 1a is, for example, an upper surface of the substrate 1. The insulating film 11 and the conductive film 12 is formed on a base substrate which is not illustrated. The base substrate is, for example, a silicon wafer, a compound semiconductor wafer or a glass substrate.

Another functional film may be formed between the insulating film 11 and the base substrate or between the conductive film 12 and the base substrate. The insulating film 11 is an example of a first film, and the conductive film 12 is an example of a second film. In addition, a material of the first film and a material of the second film are not particularly limited. The first film may be a conductive film and the second film may be an insulating film. Further, as will be described later, the first film and the second film may be different insulating films.

The insulating film 11 is, for example, an interlayer insulating film. The interlayer insulating film is preferably a low dielectric constant (Low-k) film. The insulating film 11 is not particularly limited, but is, for example, a SiO film, a SiC film, a SiN film, a SiOC film, a SiON film or a SiOCN film. Here, the SiO film means a film containing silicon (Si) and oxygen (O). An atomic ratio of Si and O in the SiO film is generally 1:2, but an atomic ratio of Si and O in the SiO film in the present disclosure is not limited to 1:2. The SiC film, the SiN film, SiOC film, the SiON film or the SiOCN film also means a film containing elements thereof, and is not limited to a stoichiometric ratio. The insulating film 11 has a recess in the substrate surface 1a. The recess is a trench, a contact hole or a via hole.

The conductive film 12 is, for example, filled in the recess of the insulating film 11. The conductive film 12 is, for example, a metal film. The metal film is, for example, a Cu film, a Co film, a Ru film, a Mo film or a W film. Further, the conductive film 12 may be a cap film. That is, although not illustrated, a second conductive film is embedded in the recess of the insulating film 11, and the conductive film 12 may cover the second conductive film. The second conductive film is made of a metal different from that of the conductive film 12.

Although not illustrated, the substrate 1 may further include a third film in the substrate surface 1a. The third film is, for example, a barrier film. The barrier film is formed between the insulating film 11 and the conductive film 12, to suppress metal diffusion into the insulating film 11 from the conductive film 12. The barrier film is not particularly limited, but is, for example, a TaN film or TiN film. Here, the TaN film means a film containing tantalum (Ta) and nitrogen (N). An atomic ratio of Ta and N in the TaN film is not limited to 1:1. The TiN film also means a film containing elements thereof, and is not limited to a stoichiometric ratio.

The step S102 of FIG. 1 includes cleaning the substrate surface 1a as illustrated in FIG. 3B. A contaminant 22 (see FIG. 3A) existing on the substrate surface 1a may be removed. The contaminant 22 includes, for example, at least one of a metal oxide and an organic material. The metal oxide is, for example, an oxide formed by a reaction of the conductive film 12 and air, and is so-called a natural oxide film. The organic material is, for example, a deposit containing carbon, and is attached in a processing process of the substrate 1.

For example, the step S102 includes supplying a cleaning gas onto the substrate surface 1a. In order to improve removal efficiency of the contaminant 22, the cleaning gas may be converted into plasma. The cleaning gas includes, for example, a reducing gas such as a H₂ gas. The reducing gas removes the contaminant 22. The step S102 is a dry processing, but may be a wet processing.

An example of a processing condition of the step S102 is represented below.
Flow rate of H₂ gas: 200 sccm to 3000 sccm
Power supply frequency for plasma generation: 400 kHz to 40 MHz
Power for plasma generation: 50 W to 1000 W
Processing time: 1 second to 60 seconds
Processing temperature: 50 degrees C. to 300 degrees C.
Processing pressure: 10 Pa to 7000 Pa

The step S103 of FIG. 1 includes forming an oxide film 32 by oxidizing a surface of the conductive film 12 as illustrated in FIG. 3C. For example, the step S103 includes forming the oxide film 32 by supplying an oxygen-containing gas onto the substrate surface 1a. The oxygen-containing gas includes at least one selected from an O₂ gas, an O₃ gas, a H₂O gas, a NO gas, a NO₂ gas, and a N₂O. The step S103 is a dry processing, but may be a wet processing.

Since the removal of the contaminant 22 is completed before the step S103, the oxide film 32 having a desired thickness and a desired film quality is obtained by the step S103. The film quality includes a surface state of a film. Unlike the natural oxide film, the film thickness and the film quality of the oxide film 32 can be controlled according to a raw material gas and a film forming condition. By forming an oxide film 32 having a desired thickness and a desired film quality, a dense self-assembled monolayer (SAM) can be formed on the surface of the conductive film 12 in the step S104 which will be described later.

An example of a processing condition of the step S103 is represented below.
Flow rate of O₂ gas: 100 sccm to 2000 sccm
Processing time: 10 seconds to 300 seconds
Processing temperature: 100 degrees C. to 250 degrees C.
Processing pressure: 200 Pa to 1200 Pa

The step S104 of FIG. 1 includes selectively forming a self-assembled monolayer 17 on the surface of the conductive film 12 with respect to a surface of the insulating film 11, using an organic compound 17A, as illustrated in FIG. 3D. Hereinafter, there is a case where the self-assembled monolayer 17 is described as a SAM 17. The SAM 17 is formed by supplying a gas of the organic compound 17A into a processing container accommodating the substrate 1. The organic compound 17A is a precursor of the SAM 17.

The organic compound 17A includes, for example, a first functional group and a second functional group provided at an end of the first functional group. The first functional group is one obtained by replacing a hydrocarbon group or at least a portion of hydrogen of the hydrocarbon group with fluorine. The first functional group is preferably a straight chain. The first functional group is preferably one obtained by replacing an alkyl group and at least a portion of the alkyl group with fluorine. Further, the first functional group may have an unsaturated bond such as a double bond. The second functional group is chemically adsorbed on the surface of the conductive film 12.

The organic compound 17A is not particularly limited, but is, for example, a thiol-based compound. The thiol-based compound is expressed with a general formula “R—SH.” The R is, for example, one obtained by replacing a hydrocarbon group or at least a portion of hydrogen of the hydrocarbon group with fluorine, and corresponds to the first functional group. The SH group corresponds to the second functional group. Specific examples of the thiol-based compound may be CF₃(CF₂)ₓCH₂CH₂SH (X is an integer of 1 to 16) and CH₃(CH₂)ₓSH (X is an integer of 1 to 17).

The thiol-based compound is more easily chemically adsorbed on the surface of the conductive film 12, compared with the surface of the insulating film 11. Therefore, the SAM 17 is selectively formed on the surface of the conductive film 12 with respect to the surface of the insulating film 11. The SAM 17 is hardly formed on the surface of the insulating film 11. Further, the SAM 17 is hardly formed even onto a surface of the barrier film which is not illustrated.

In a case where the oxide film 32 is formed before the SAM 17 is formed, a density of the SAM 17 can be increased, compared with a case where the oxide film 32 is not formed, and hence it is possible to improve block performance of the SAM 17 in the step S106 which will be described later. The thiol-based compound is chemically adsorbed while reducing the oxide film 32, and therefore, the oxide film 32 may not remain after the step S104 (see FIG. 3D).

In addition, the organic compound 17A is not limited to the thiol-based compound. For example, the organic compound 17A may be a phosphonic acid-based compound, a carboxylic acid-based compound, an olefin-based compound or a nitro-based compound. The phosphonic acid-based compound is expressed with a general formula “R—P(═O)(OH)₂.” The carboxylic acid-based compound is expressed with a general formula “R—COOH.” The olefin-based compound is expressed with a general formula “R—CH═CH₂.” The nitro-based compound is expressed with a general formula “R—NO₂.”

Further, the organic compound 17A may be an organic silane-based compound. The organic silane-based compound is, for example, a trichlorosilane-based organic compound, a methoxysilane-based organic compound or an ethoxysilane-based organic compound. The trichlorosilane-based organic compound is expressed with a general formula “R—SiCl₃.” The methoxysilane-based organic compound is expressed with a general formula “R—Si(OCH₃)₃.” The ethoxysilane-based organic compound is expressed with a general formula “R—Si(OCH₂CH₃)₃.”

In the general formula of the organic compound 17A, the R is, for example, one obtained by replacing a hydrocarbon group or at least a portion of hydrogen of the hydrocarbon group with fluorine. Specifically, the R is, for example, “CF₃—(CF₂)ₓ—CH₂—CH₂—” or “CH₃—(CH₂)ₓ—.” The X is an integer of 1 to 17.

An example of a processing condition of the step S104 is represented below.
Flow rate of gas of organic compound 17A: 50 sccm to 500 sccm
Processing time: 10 seconds to 1800 seconds
Processing temperature: 100 degrees C. to 350 degrees C.
Processing pressure: 100 Pa to 14000 Pa

As illustrated in FIG. 3D, the organic compound 17A is selectively chemically adsorbed on the surface of the conductive film 12 with respect to the surface of the insulating film 11. However, since the selectivity is not complete, there is a case where the organic compound 17A is attached to the surface of the insulating film 11. The organic compound 17A attached to the surface of the insulating film 11 is unnecessary and obstructive in formation of a target film 18 (the step S106).

Accordingly, in order to remove the unnecessary and obstructive organic compound 17A attached to the surface of the insulating film 11, the step S105 of FIG. 1 includes supplying a removal gas onto the substrate surface 1a as illustrated in FIG. 3E. Before the target film 18 is formed, the unnecessary and obstructive organic compound 17A may be removed from the surface of the insulating film 11. Therefore, the target film 18 may be selectively formed on the surface of the insulating film 11.

In order to selectively form the target film 18, (1) it is important to increase the density of the SAM 17 on the surface of the conductive film 12, but (2) it is also important to remove the unnecessary and obstructive organic compound 17A attached to the surface of the insulating film 11. The supply of the removal gas decreases the density of the SAM 17 on the surface of the conductive film 12, but can remove the unnecessary and obstructive organic compound 17A attached to the surface of the insulating film 11.

The supply of the removal gas is especially effective in a case where it is easy for the organic compound 17A to suppress the formation of the target film 18. This is because, even when the density of the SAM 17 on the surface of the conductive film 12 is decreased, it is possible to suppress the formation of the target film 18 using the remaining SAM 17. In this case, removing the unnecessary and obstructive organic compound 17A attached to the surface of the insulating film 11 is more important in selectively forming the target film 18 than decrease of the density of the SAM 17 on the surface of the conductive film 12.

In order to improve removal efficiency of the unnecessary and obstructive organic compound 17A, the removal gas may be converted into plasma. The removal gas converted into the plasma, includes, for example, at least one selected from a H₂ gas, a NH₃ gas, an O₂ gas, an Ar gas, N₂ gas, and a He gas.

The removal gas may include an O₃ gas). The O₃ gas) may efficiently remove the unnecessary and obstructive organic compound 17A without being converted into plasma.

A supply time of the removal gas is, for example, 5 seconds or less. Here, the supply time of the removal gas is a time for which the removal gas is supplied into the processing container accommodating the substrate 1. If the supply time of the removal gas is 5 seconds or less, the SAM 17 can remain on the surface of the conductive film 12, and thus it is possible to suppress the formation of the target film 18 on the surface of the conductive film 12 using the SAM 17 in the step S106. The supply time of the removal gas is preferably 3 seconds or less, and is more preferably 1 second or less. Further, in order to remove the unnecessary and obstructive organic compound 17A attached to the surface of the insulating film 11, the supply time of the removal gas is preferably 0.1 seconds or more, and is more preferably 0.5 or more.

An example of a processing condition of the step S105 is represented below.
Flow rate of removal gas: 50 sccm to 5000 sccm
Processing time: 0.1 seconds to 5 seconds
Processing temperature: 100 degrees C. to 350 degrees C.
Processing pressure: 100 Pa to 7000 Pa

As illustrated in FIG. 3F, the step S106 of FIG. 1 includes forming the target film 18 on the surface of the insulating film 11 while suppressing the formation of the target film 18 on the surface of the conductive film 12, using the SAM 17. The target film 18 is, for example, an insulating film.

The target film 18 is not particularly limited, but is, for example, a SiO film, an AlO film, a HfO film, a ZrO film, a TiN film or a TiO film. Here, the AlO film means a film containing aluminum (Al) and oxygen (O). An atomic ratio of Al and O in the AlO film is generally 2:3, but an atomic ratio of Al and O in the AlO film in the present disclosure is not limited to 2:3. The HfO film, the ZrO film, TiN film or the TiO film also means a film containing elements thereof, and is not limited to a stoichiometric ratio.

The target film 18 is formed, for example, using a chemical vapor deposition (CVD) method or an atomic layer deposition (ALD) method. In a case where the target film 18 is formed using the ALD method, a precursor gas of the target film 18 and a reaction gas are alternately supplied onto the substrate surface 1a. The precursor gas of the target film 18 contains, for example, a metal element or a semimetal element.

The reaction gas reacts with the precursor gas of the target film 18, to form the target film 18. The reaction gas is, for example, an oxidizing gas or a nitriding gas. The oxidizing gas forms an oxide film of the metal element or the semimetal element, which is contained in the precursor gas. The nitriding gas forms a nitride film of the metal element or the semimetal element, which is contained in the precursor gas.

Further, the reaction gas may be a reducing gas. The reducing gas forms a metal film or a semiconductor film, using the metal element or the semimetal element, which is contained in the precursor gas of the target film 18. The target film 18 may be a metal film or a semiconductor film.

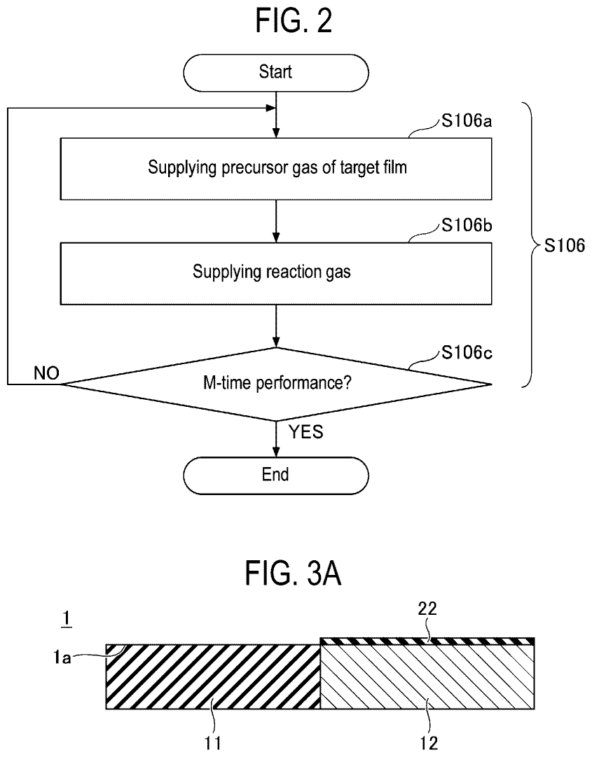

The step S106 includes steps S106a to S106c shown in FIG. 2. In addition, a step of exhausting various gases remaining in the processing container by supplying an inert gas such as an argon gas into the processing container may be provided between an n-time (n is a natural number of 1 or more) step S106a and an n-time step S106b or between an n-time step S106b and an (n+1)-time step S106a.

The step S106a includes supplying the precursor gas of the target film 18 onto the substrate surface 1a. Since the SAM 17 is formed on the surface of the conductive film 12, the precursor gas is selectively adsorbed on the surface of the insulating film 11. An example of a processing condition of the step S106a is represented below. Further, in the following processing condition, a trimethylaluminum (TMA) gas is a precursor gas of the AlO film.
Flow rate of TMA gas: 1 sccm to 300 sccm (preferably 50 sccm)
Processing time: 0.1 seconds to 2 seconds
Processing temperature: 100 degrees C. to 250 degrees C.
Processing pressure: 133 Pa to 1200 Pa

The step S106b includes supplying the reaction gas onto the substrate surface 1a. The reaction gas reacts with the precursor gas of the target film 18, to form the target film 18. An example of a processing condition of the step S106b is represented below. Further, in the following processing condition, a H₂O gas reacts with the TMA gas, to form the AlO film.
Flow rate of H₂O gas: 10 sccm to 200 sccm
Processing time: 0.1 seconds to 2 seconds
Processing temperature: 100 degrees C. to 250 degrees C.
Processing pressure: 133 Pa to 1200 Pa

The step S106c includes checking whether the steps S106a and S106b have been performed a set number of times (M times). The set number of times (M times) is set according to a thickness of the target film 18, and is, for example, 20 times to 100 times. The target film thickness of the target film 18 is, for example, 2 nm to 10 nm.

If the number of times of performance does not reach the set number of times (M times) (the step S106c, “NO”), the film thickness of the target film 18 has not reached the target film thickness, and therefore, the steps S106a and S106b are re-performed. On the other hand, if the number of times of performance reaches the set number of times (M times) (the step S106c, “YES”), the processing of FIG. 2 is ended since the film thickness of the target film 18 reaches the target film thickness.

Table 1 represents an example of a material combination of the insulating film 11 as the first film, the conductive film 12 as the second film, the target film 18, and the organic compound 17A.

TABLE 1

| First Film | Second Film | | |
|---|---|---|---|
| (Insulating | (Conductive | Target | Organic Compound |
| Film) | Film) | Film | (SAM Material) |
| SiO | Cu | SiO | Thiol-Based Compound |
| SiC | Co | AlO | Phosphonic Acid-Based |
| | | | Compound |
| SiN | Ru | HfO | Carboxylic Acid-Based |
| | | | Compound |
| SiOC | Mo | ZrO | Olefin-Based Compound |
| SiON | W | | Nitro-Based Compound |
| SiOCN | | | |

As shown in Table 1, in a case where the first film is the insulating film 11 and the second film is the conductive film 12, the organic compound 17A is preferably a thiol-based compound, a phosphonic acid-based compound, a carboxylic acid-based compound, an olefin-based compound or a nitro-based compound. A combination of materials of the insulating film 11, the conductive film 12, the target film 18, and the organic compound 17A may be an arbitrary combination selected from materials described in Table 1.

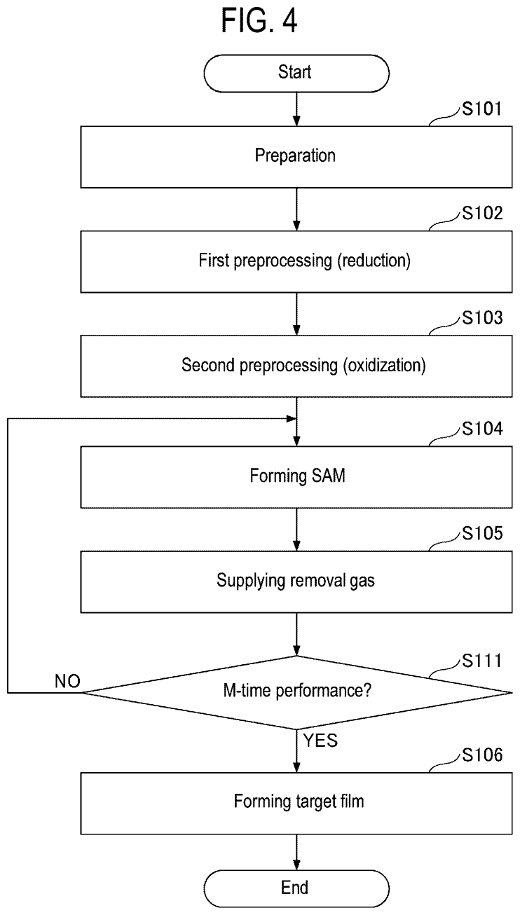

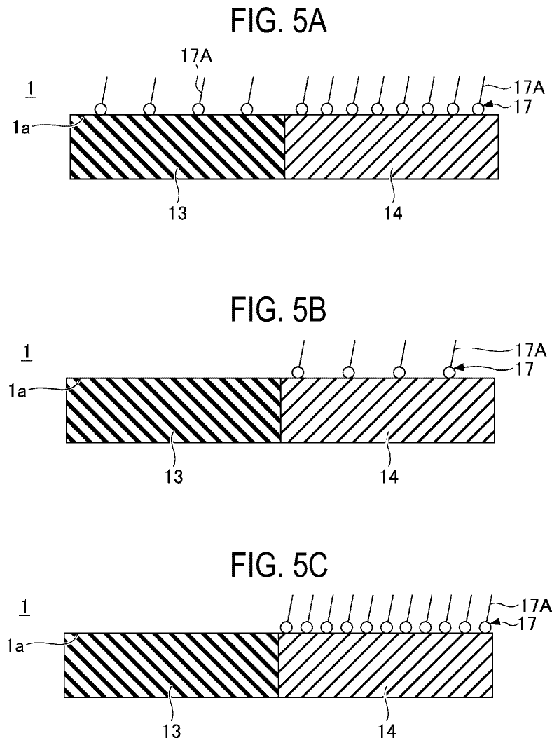

Next, a film forming method according to a modification is described with reference to FIGS. 4 and 5A to 5C. As illustrated in FIG. 4, the film forming method may include step S111 in addition to the step S101 to S106, and may repeatedly perform the steps S104 and S105 N times (N is a natural number of 2 or more). The repeated performance of the steps S104 and S105 a plurality of times is especially effective when selectivity of the organic compound 17A is low as illustrated in FIG. 5A.

As an example of a case where the selectivity of the organic compound 17A is low may be a case where the first film and the second film are different insulating films. As illustrated in FIG. 5A, the substrate 1 may include a first insulating film 13 and a second insulating film 14 in different regions of the substrate surface 1a. The organic compound 17A is selectively chemically adsorbed on a surface of the second insulating layer 14 with respect to a surface of the first insulating film 13. However, the selectivity is low.

Therefore, in order to remove the unnecessary and obstructive organic compound 17A attached to the surface of the first insulating film 13 as illustrated in FIG. 5B, the step S105 includes supplying a removal gas onto the substrate surface 1a. Before the target film 18 is formed, the unnecessary and obstructive organic compound 17A can be removed from the surface of the first insulating film 13.

As such, the steps S104 and S105 are repeatedly performed a plurality of times, so that a density of the SAM 17 on the surface of the second insulating film 14 can be increased as illustrated in FIG. 5C. After that, by performing the step S106, the target film 18 can be selectively formed on the surface of the first insulating film 13 with respect to the surface of the second insulating film 14, and the selectivity can be improved.

Table 2 represents an example of a material combination of the first insulating film 13 as the first film, the second insulating film 14 as the second film, the target film 18, and the organic compound 17A.

TABLE 2

| First Film | Second Film | Target | Organic Compound |
|---|---|---|---|
| (Insulating Film) | (Insulating Film) | Film | (SAM Material) |
| Si | SiO | SiO | Organic Silane-Based |
| | | | Compound |
| SiC | | AlO | |
| SiN | | HfO | |
| SiOC | | ZrO | |
| SiON | | TiN | |
| SiOCN | | TiO | |

As shown in Table 2, in a case where the first film is the first insulating film 13 and the second film is the second insulating film 14 different from the first insulating film 13, the organic compound 17A is preferably an organic silane-based compound. A combination of materials of the first insulating film 13, the second insulating film 14, the target film 18, and the organic compound 17A may be an arbitrary combination selected from materials described in Table 2.

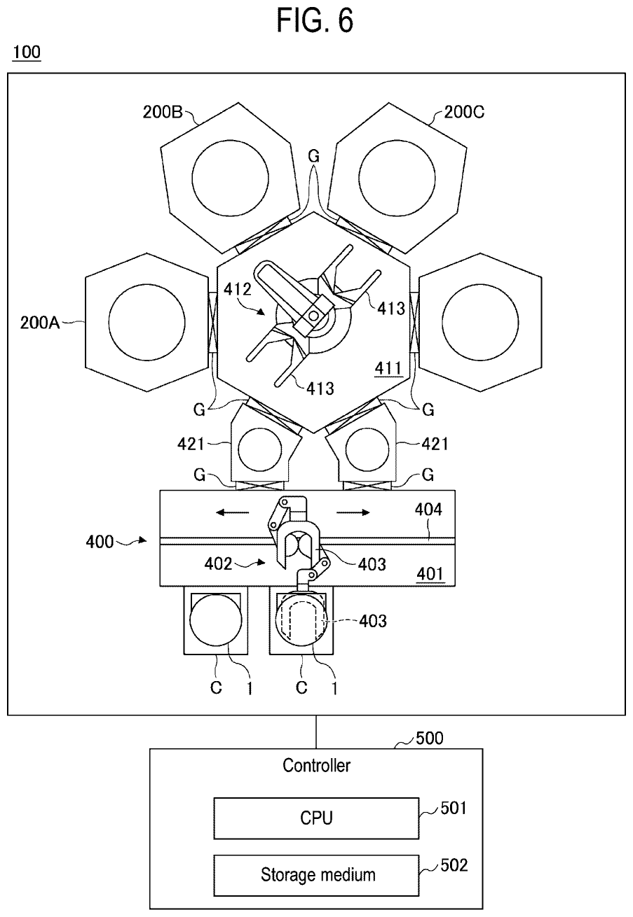

Next, a film forming apparatus 100 configured to perform the film forming method shown in FIG. 1 or 4 is described with reference to FIG. 6. As illustrated in FIG. 6, the film forming apparatus 100 includes a first processor 200A, a second processor 200B, a third processor 200C, and a controller 500. The first processor 200A performs the steps S102 and S103 of FIG. 1 or 4. The second processor 200B performs the steps S104 and S105 of FIG. 1 or 4. The third processor 200C performs the step S106 of FIG. 1 or 4. The first processor 200A, the second processor 200B, and the third processor 200C have a same structure. Therefore, only the first processor 200A may perform all the steps S102 to S106 of FIG. 1 or 4. A transfer part 400 transfers a substrate 1 to the first processor 200A, the second processor 200B, and the third processor 200C. The controller 500 controls the first processor 200A, the second processor 200B, the third processor 200C, and the transfer part 400.

The transfer part 400 includes a first transfer chamber 401 and a first transfer mechanism 402. An internal atmosphere of the first transfer chamber 401 is an air atmosphere. The first transfer mechanism 402 is provided inside the first transfer chamber 401. The first transfer mechanism 402 includes an arm 403 configured to hold the substrate 1, and travels along a rail 404. The rail 404 extends in an arrangement direction of carriers C.

Further, the transfer part 400 includes a second transfer chamber 411 and a second transfer mechanism 412. An internal atmosphere of the second transfer chamber 411 is a vacuum atmosphere. The second transfer mechanism 412 is provided inside the second transfer chamber 411. The second transfer mechanism 412 includes an arm 413 configured to hold the substrate 1, and the arm 413 is located to be movable in a vertical direction and a horizontal direction and be rotatable around a vertical axis. The first processor 200A, the second processor 200B, and the third processor 200C are connected to the second transfer chamber 411 through different gate valves G.

Further, the transfer part 400 includes a load lock chamber 421 between the first transfer chamber 401 and the second transfer chamber 411. An internal atmosphere of the load lock chamber 421 is changed between the vacuum atmosphere and the air atmosphere by a pressure adjustment mechanism which is not illustrated. Accordingly, it is possible to always maintain an interior of the second transfer chamber 411 in the vacuum atmosphere. In addition, it is possible to suppress a gas from being introduced into the second transfer chamber 411 from the first transfer chamber 401. Gate values G are provided between the first transfer chamber 401 and the load lock chamber 421 and between the second transfer chamber 411 and the load lock chamber 421.

The controller 500 is, for example, a computer, and includes a central processing unit (CPU) 501 and a storage medium 502 such as a non-transitory computer readable memory. A program for controlling various processings performed in the film forming apparatus 100 is stored in the storage medium 502. The controller 500 executes the program stored in the storage medium 502 in the CPU 501, to control an operation of the film forming apparatus 100. The controller 500 controls the first processor 200A, the second processor 200B, the third processor 200C, and the transfer part 400, thereby performing the film forming method.

Next, an operation of the film forming apparatus 100 is described. First, the first transfer mechanism 402 takes out the substrate 1 from the carrier C, transfers the taken-out substrate 1 to the load lock chamber 421, and exits from the load lock chamber 421. Subsequently, the internal atmosphere of the load lock chamber 421 is changed from the air atmosphere to the vacuum atmosphere. After that, the second transfer mechanism 412 takes out the substrate 1 from the load lock chamber 421, and transfers the taken-out substrate 1 to the first processor 200A.

Subsequently, the first processor 200A performs the steps S102 and S103 of FIG. 1 or 4. After that, the second transfer mechanism 412 takes out the substrate 1 from the first processor 200A, and transfers the taken-out substrate 1 to the second processor 200B. During that time, a peripheral atmosphere of the substrate 1 may be maintained as the vacuum atmosphere.

Subsequently, the second processor 200B performs the steps S104 and S105 of FIG. 1 or 4. The second processor 200B may repeatedly perform the steps S104 and S105 a preset number of times as illustrated in FIG. 4. After that, the second transfer mechanism 412 takes out the substrate 1 from the second processor 200B, and transfers the taken-out substrate 1 to the third processor 200C. During that time, the peripheral atmosphere of the substrate 1 may be maintained as the vacuum atmosphere.

Subsequently, the third processor 200C performs the step S106 of FIG. 1 or 4. After that, the second transfer mechanism 412 takes out the substrate 1 from the third processor 200C, transfers the taken-out substrate 1 to the load lock chamber 421, and exits from the load lock chamber 421. Continuously, the internal atmosphere of the load lock chamber 421 is changed from the vacuum atmosphere to the air atmosphere. After that, the first transfer mechanism 402 takes out the substrate 1 from the load lock chamber 421, and accommodates the taken-out substrate 1 in the carrier C. In addition, processing of the substrate 1 is ended.

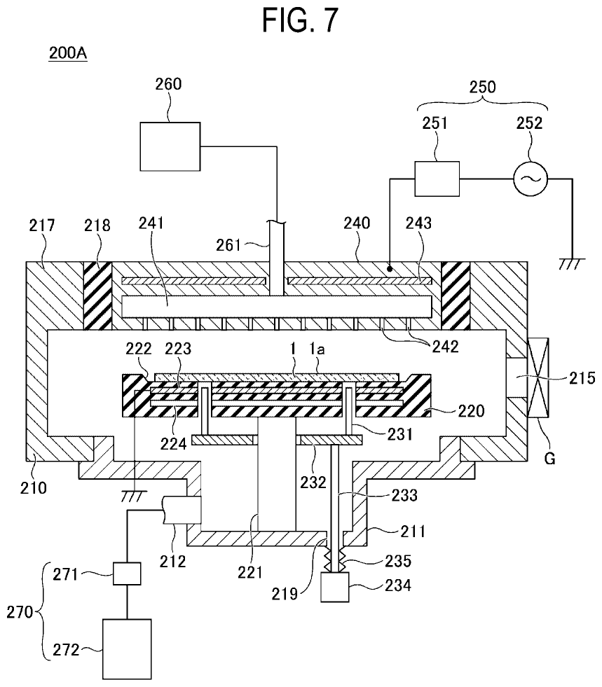

Next, the first processor 200A is described with reference to FIG. 7. In addition, the second processor 200B and the third processor 200C are configured identically to the first processor 200A, and therefore, illustration and description are omitted.

The first processor 200A includes a substantially cylindrical airtight processing container 210. An exhaust chamber 211 is provided in a central portion of a bottom wall of the processing container 210. The exhaust chamber 211 has, for example, a substantially cylindrical shape which protrudes downward. An exhaust pipe 212 is connected to the exhaust chamber 211, for example, on a side surface of the exhaust chamber 211.

An exhaust source 272 is connected to the exhaust pipe 212 via a pressure controller 271. The pressure controller 271 includes, for example, a pressure adjustment valve such as a butterfly valve. The exhaust pipe 212 is configured such that a pressure inside the processing chamber 210 can be reduced by the exhaust source 272. The pressure controller 271 and the exhaust source 272 constitute a gas exhaust mechanism 270 configured to exhaust a gas in the processing container 210.

A transfer port 215 is provided in a side surface of the processing container 210. The transfer port 215 is opened and closed by the gate valve G. Loading/unloading of the substrate 1 between an interior of the processing container 210 and the transfer chamber 411 (see FIG. 6) is performed via the transfer port 215.

A stage 220 which is a holder configured to hold the substrate 1 is provided in the processing container 210. The stage 220 holds the substrate 1 horizontally while making the substrate surface 1a face upward. The stage 220 is formed in a substantially circular shape in plan view and is supported by a support member 221. A substantially circular recess 222 is formed in a surface of the stage 220 to place therein the substrate 1 having a diameter of, for example, 300 mm. The recess 222 has an inner diameter slightly larger than the diameter of the substrate 1. A depth of the recess 222 is substantially the same as, for example, a thickness of the substrate 1. The stage 220 is made of a ceramic material such as aluminum nitride (AlN). Further, the stage 220 may be made of a metallic material such as nickel (Ni). Instead of the recess 222, a guide ring configured to guide the substrate 1 may be provided at a peripheral edge of the surface of the stage 220.

A lower electrode 223 which is, for example, grounded is embedded in the stage 220. A heating mechanism 224 is embedded below the lower electrode 223. The heating mechanism 224 is fed with power from a power supply (not illustrated), based on a control signal from the controller 500 (see FIG. 6), to heat the substrate 1 placed on the stage 220 to a set temperature. In a case where the entire stage 220 is made of a metal, the entire stage 220 functions as a lower electrode, and therefore, the lower electrode 223 may not be embedded in the stage 220. The stage 220 is provided with a plurality of (e.g., three) lifting pins 231 configured to hold and vertically move the substrate 1 placed on the stage 220. A material of the lifting pins 231 may be, for example, ceramic such as alumina (Al₂O₃) or quartz. Lower ends of the lifting pins 231 are installed on a support plate 232. The support plate 232 is connected to a lifting mechanism 234 provided outside the processing container 210 via a lifting shaft 233.

The lifting mechanism 234 is installed, for example, below the exhaust chamber 211. A bellows 235 is provided between the lifting mechanism 234 and an opening 219 for the lifting shaft 233, which is formed in a lower surface of the exhaust chamber 211. The support plate 232 may have a shape which can be moved vertically without interfering with the support member 221 of the stage 220. The lifting pins 231 are configured to be moved vertically between above the surface of the stage 220 and below the surface of the stage 220 by the lifting mechanism 234.

A gas supply 240 is provided in a ceiling wall 217 of the processing container 210 via an insulating member 218. The gas supply 240 forms an upper electrode and faces the lower electrode 223. A radio frequency power supply 252 is connected to the gas supply 240 via a matcher 251. The radio frequency power supply 252 applies radio frequency power of 400 KHZ to 40 MHz to the upper electrode (the gas supply 240), so that a radio frequency electric field is generated between the upper electrode (the gas supply 240) and the lower electrode 223, thereby generating capacitively coupled plasma. A plasma generator 250 configured to generate plasma includes the matcher 251 and the radio frequency power supply 252. Further, the plasma generator 250 is not limited to the capacitively coupled plasma, and may generate another plasma such as inductively coupled plasma.

The gas supply 240 includes a hollow gas supply chamber 241. In a bottom surface of the gas supply chamber 241, a plurality of holes 242 configured to disperse and supply a processing gas into the processing container 210 are, for example, evenly arranged. A heating mechanism 243 is embedded in the gas supply 240, for example, above the gas supply chamber 241. The heating mechanism 243 is fed with power from a power supply (not illustrated), based on a control signal from the controller 500, to be heat to a set temperature.

A gas supply mechanism 260 is connected to the gas supply chamber 241 via a gas supply path 261. The gas supply mechanism 260 supplies a gas used in at least one of the steps S102 to S106 of FIG. 1 or 4 to the gas supply chamber 241 via the gas supply path 261. Although not illustrated, the gas supply mechanism 260 includes, for each kind of gas, an individual pipe, an opening/closing valve provided in the middle of the individual pipe, and a flow rate controller provided in the middle of the individual pipe. When the opening/closing pipe opens the individual pipe, the gas is supplied to the gas supply path 261 from a gas supply source. A supply amount of the gas is controlled by the flow rate controller. On the other hand, when the opening/closing valve closes the individual pipe, the supply of the gas to the gas supply path 261 from the gas supply source is stopped.

According to the present disclosure in some embodiments, it is possible to selectively form a target film in a desired region, using a self-assembled monolayer.

In the above, an embodiment of the film forming method and the film forming apparatus according to the present disclosure have been described, but the present disclosure is not limited to the embodiment and the like. Various changes, modifications, substitutions, additions, deletions, and combinations are possible within the scope of claims. These are naturally considered as being within the technical scope of the present disclosure.

This application is based upon and claims the benefit of priority from Japanese Patent Application No. 2022-173129, filed on Oct. 28, 2022, the entire contents of which are incorporated herein by reference.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
(A) preparing a substrate including a first film and a second film made of a material different from that of the first film in different regions of a surface of the substrate;
(B) selectively forming a self-assembled monolayer on a surface of the second film with respect to a surface of the first film, using an organic compound;
(C) after the (B), supplying a removal gas for removing the organic compound attached to the surface of the first film onto the surface of the substrate; and
(D) after the (C), forming a target film on the surface of the first film while suppressing formation of the target film on the surface of the second film, using the self-assembled monolayer.

2. The film forming method of claim 1, wherein the (C) includes converting the removal gas into plasma.

3. The film forming method of claim 2, wherein the removal gas includes at least one selected from a H₂ gas, a NH₃ gas an O₂ gas, an Ar gas, N₂ gas, and a He gas.

4. The film forming method of claim 1, wherein the removal gas includes an O₃ gas).

5. The film forming method of claim 1, wherein a supply time of the removal gas is 5 seconds or less.

6. The film forming method of claim 1, wherein the (B) and the (C) are repeatedly performed a plurality of times.

7. The film forming method of claim 1, wherein the first film is an insulating film, the second film is a conductive film, and the organic compound is a thiol-based compound, a phosphonic acid-based compound, a carboxylic acid-based compound, an olefin-based compound or a nitro-based compound.

8. The film forming method of claim 1, wherein the first film and the second film are different insulating films, and the organic compound is an organic silane-based compound.

9. A film forming apparatus comprising:
a processing container;
a holder configured to hold a substrate inside the processing container;
a gas supply mechanism configured to supply a gas into the processing container;
a gas exhaust mechanism configured to exhaust the gas from the interior of the processing container;
a transfer mechanism configured to load/unload the substrate with respect to the processing container; and
a controller configured to control the gas supply mechanism, the gas exhaust mechanism, and the transfer mechanism, to perform the film forming method of claim 1.
